(19) United States
(12) Patent Application Publication
(10) Pub. No.: US 2024/0112936 A1
(43) Pub. Date: Apr. 4, 2024

(54) SUBSTRATE TRANSFER MODULE AND SUBSTRATE TRANSFER METHOD

(71) Applicant: Tokyo Electron Limited, Tokyo (JP)

(72) Inventors: Mitsuyori SUWA, Tokyo (JP); Takehiro SHINDO, Nirasaki City (JP); Akio TATEISHI, Nirasaki City (JP)

(21) Appl. No.: 18/472,157

(22) Filed: Sep. 21, 2023

(30) Foreign Application Priority Data
Sep. 30, 2022 (JP) 2022-157386

(51) Int. Cl. H01L 21/677

(52) U.S. Cl. CPC H01L 21/67709; H01L 21/67712; H01L 21/67742; H01L 21/67745

(57) ABSTRACT

A substrate transfer module includes: a transfer space in which a transport body including a magnet moves in a lateral direction while being levitated from a floor by magnetic force to transfer a substrate; a hole forming member having a through-hole formed in a vertical direction; a partition member that forms the floor by overlapping a hole edge portion of the through-hole in the vertical direction to block the through-hole, and defines the transfer space having an atmosphere that is separated from a non-transfer space including a portion under the floor outside the transfer space; and a plurality of electromagnets provided in the non-transfer space at positions overlapping the through-hole to move the transport body in the lateral direction, wherein each of the electromagnets is individually fed with power from a power feeder provided in the non-transfer space via a power feed line.

### CROSS-REFERENCE TO RELATED APPLICATION

This application is based upon and claims the benefit of priority from Japanese Patent Application No. 2022-157386, filed on Sep. 30, 2022, the entire contents of which are incorporated herein by reference.

### TECHNICAL FIELD

The present disclosure relates to a substrate transfer module and a substrate transfer method.

### BACKGROUND

For example, in a system (substrate processing apparatus) that processes semiconductor wafers (hereinafter also referred to as “wafers”), which are substrates, wafers are transferred between a carrier that accommodates the wafers and a substrate processing chamber in which the wafers are processed. Various types of substrate transfer mechanisms are used to transfer wafers. The Applicant is developing a substrate processing apparatus that performs substrate transfer by a substrate transport body that uses magnetic levitation.

As an apparatus using magnetic levitation, for example, Patent Document 1 discloses a configuration including a planar motor having arrayed coils, and a transfer unit that moves on the planar motor. This transfer unit includes a base that has arrayed magnets and is magnetically levitated by a planar motor, and a substrate support member that supports a substrate. In addition, Patent Document 2 discloses a technique related to an arrangement of a magnet array in a displacement device that includes a stator provided with a coil and a movable stage provided with a magnet array and relatively moves between the stator and the movable stage.

### PRIOR ART DOCUMENTS

### Patent Documents

Patent Document 1: Japanese Patent Laid-Open Publication No. 2014-531189

### SUMMARY

According to one embodiment of the present disclosure, there is provided a substrate transfer module. The substrate transfer module includes: a transfer space in which a transport body including a magnet moves in a lateral direction while being levitated from a floor by magnetic force to transfer a substrate; a hole forming member having a through-hole formed in a vertical direction; a partition member that forms the floor by overlapping a hole edge portion of the through-hole in the vertical direction to block the through-hole, and defines the transfer space having an atmosphere that is separated from a non-transfer space including a portion under the floor outside the transfer space; and a plurality of electromagnets provided in the non-transfer space at positions overlapping the through-hole to move the transport body in the lateral direction, wherein each of the electromagnets is individually fed with power from a power feeder provided in the non-transfer space via a power feed line.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a substrate processing apparatus in a first embodiment.

FIG. 2 is a see-through perspective view illustrating a transport body and a floor in the first embodiment.

FIG. 3 is a vertical cross-sectional side view taken along line A-A′ in FIG. 2.

FIG. 4 is a bottom perspective view illustrating a frame body in the first embodiment.

FIG. 5 is an enlarged view of a portion B in FIG. 4.

FIG. 6 is a partially exploded view of the floor in the first embodiment.

FIG. 7 is a bottom perspective view of the floor in a second embodiment.

FIG. 8 is a cross-sectional view taken along line C-C′ in FIG. 7.

FIG. 9 is a vertical cross-sectional side view of the floor in a third embodiment.

FIG. 10 is a vertical cross-sectional side view of the floor in a fourth embodiment.

FIG. 11 is a vertical cross-sectional side view of the floor in a fifth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

### <Substrate Processing Apparatus>

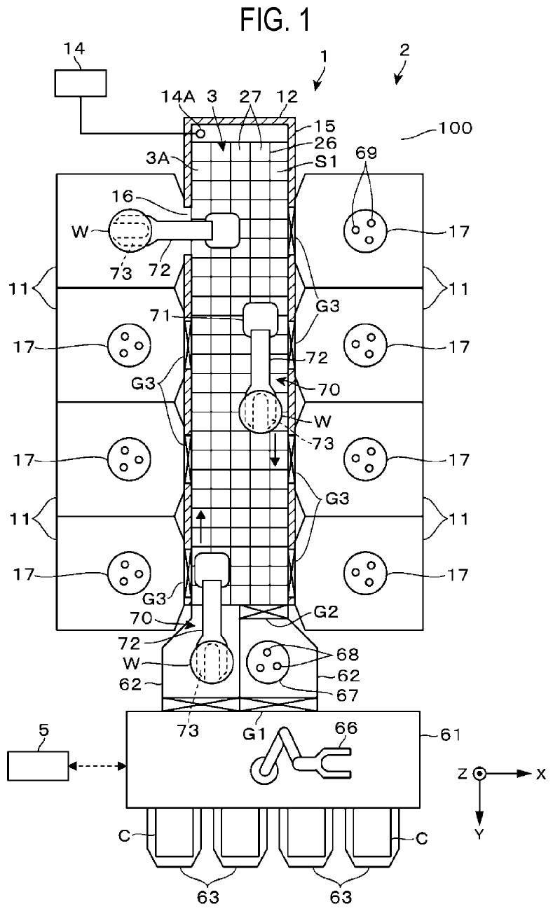

An embodiment of a substrate transfer module 1 of the present disclosure will be described below with reference to FIG. 1. As illustrated in FIG. 1, the substrate transfer module 1 constitutes, for example, a multi-chamber type substrate processing apparatus 2 including a plurality of processing containers 11 capable of performing various types of processing on wafers W, which are substrates, and transfers wafers W to corresponding processing containers 11 for processing the wafers.

Before describing the substrate transfer module 1, the overall structure of the substrate processing apparatus 2 will be described. The substrate processing apparatus 2 is installed in a clean room in a semiconductor device manufacturing factory. As illustrated in FIG. 1, the substrate processing apparatus 2 includes an atmospheric transfer chamber 61, a load-lock chamber 62, a housing 12, and a plurality of processing containers 11, which are arranged in the horizontal direction in that order from the atmospheric transfer chamber 61 side. In the substrate processing apparatus 2 of this example, the processing containers 11 are configured to process wafers W under a vacuum atmosphere, and a transfer space S1 of the wafer W formed within the housing 12 has a vacuum atmosphere.

In the following description of the entire substrate processing apparatus 2, an XYZ orthogonal coordinate system is used, and the XY direction is the horizontal direction. In addition, in FIG. 1, the Y direction is the front-rear direction, and the X direction is the left-right direction. In the front-rear direction, the housing 12 is on the inner side (rearward side), and the atmosphere transfer chamber 61 is on the front side (forward side). In addition, the vertical direction is illustrated as the Z direction.

A load port 63 is provided on the forward side of the atmospheric transfer chamber 61. The load port 63 is configured as a stage on which a carrier C accommodating wafers W to be processed is placed. For example, four load ports 63 are installed side by side in the left-right direction. As the carriers C, for example, front opening unified pods (FOUPs) may be used. The atmospheric transfer chamber 61 has an atmospheric pressure (normal pressure) atmosphere, and, for example, clean air downflow is formed therein. Further, a transfer mechanism 66 made up of, for example, a multi joint arm is provided inside the atmosphere transfer chamber 61 to transfer wafers W between the carriers C and the load-lock chamber 62.

Between the atmospheric transfer chamber 61 and the housing 12, for example, two load-lock chambers 62 are installed side by side. The load-lock chamber 62 is configured to switch between an atmospheric pressure atmosphere and a vacuum atmosphere, and includes a delivery stage 67 on which a wafer W is placed, and lifting pins 68 that push up and hold the wafer W from below. For example, three lifting pins 68 are provided at equal intervals along the circumferential direction, and configured to be movable upward and downward. Lifting pins 69, which will be described later, are also configured in the same manner. The space between the load-lock chamber 62 and the atmosphere transfer chamber 61 and the space between the load-lock chamber 62 and the housing 12 are configured to be openable/closable by gate valves G1 and G2, respectively.

As illustrated in FIG. 1, the housing 12 is elongated in the front-rear direction and has a rectangular shape in plan view. The bottom of the housing 12 is configured as a floor 3, and a wafer W transfer space S1 is formed above the floor 3 within the housing 12. An evacuation mechanism 14 is provided in the housing 12, and the evacuation mechanism 14 opens at its downstream end inside the housing 12 to depressurize the transfer space S1 to a vacuum atmosphere. A total of eight processing containers 11 are connected to each of the right and left side walls 15 of the housing 12 of the present example. In the side walls 15, openings 16 are formed for respective processing containers 11 such that a wafer W is transferred to each processing container 11 through corresponding one of the openings 16, and each opening 16 is configured to be openable/closable by a gate valve G3. Between the housing 12 and the processing containers 11, carry-in/out of wafers W are performed via through these openings 16.

Each processing container 11 is depressurized to a vacuum atmosphere by an evacuation mechanism (not illustrated). A stage 17 is provided inside each processing container 11, and a wafer W is subjected to predetermined processing in a state of being placed on the stage 17. Examples of the processing to be performed on the wafers W include etching, film formation, annealing, ashing, and the like. Each processing container 11 is provided with processing modules for performing such processing, specifically a stage 17, a heater configured to adjust the temperature of the stage 17, a gas supplier such as a shower head that supplies gas into the processing container 11, a device group for gas circulation, such as valves, configured to introduce gas into the gas supplier, and an exhaust mechanism, such as a valve or a pump, configured to exhaust the interior of the processing container 11.

For example, when a wafer W is heated while being processed, the stage 17 is provided with a heater. When a processing gas is used in the processing to be performed on the wafer W, the processing container 11 is provided with a processing gas supplier configured with a shower head or the like. Illustrations of the heaters and the processing gas suppliers are omitted from the drawing. In addition, the stage 17 is provided with lifting pins 69 for delivery of a wafer W to be carried in or out.

A transport body 70 configured to transport a wafer W is disposed in the housing 12. As illustrated in FIG. 1, the transport body 70 is provided with a main body 71 that is used in the state of being disposed on the floor 3, and the main body 71 is provided with a substrate holder 72 configured to horizontally hold a wafer W to be transferred. The substrate holder 72 is provided to protrude in the horizontal direction from the main body 71.

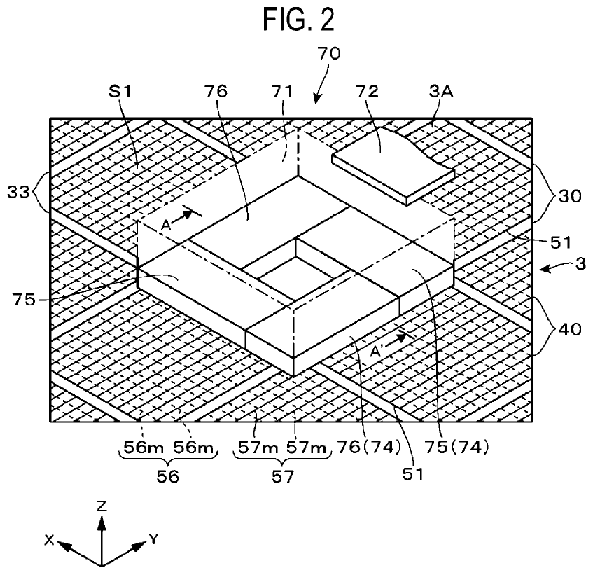

FIG. 2 is a see-through perspective view clearly showing the bottom surface of the main body 71 of the transport body 70 and the interior of the floor 3, through the upper portion of the main body 71 of the transport body 70 and the upper portion of the case body 40 of the floor 3, which will be described later. As will be described later in detail, the transport body 70 is configured to be movable in the lateral direction in the state of being levitated from a floor surface 3A (the top surface of the floor 3) by using the repulsive force between a magnet unit 74 provided on the bottom surface of the main body 71 and a large number of electromagnets provided in the floor 3. Such levitation movement of the transport body 70 is intended to prevent the generation of dust and to keep the transfer space S1 at a high degree of cleanliness.

The movement in the lateral direction used herein includes the movement of one arbitrary point of the transport body 70 in the lateral direction. That is, in addition to the movement of the transport body 70 to a position separated on the floor in the front-rear direction (the Y-direction) or the left-right direction (the X-direction), the movement in the lateral direction includes the rotational movement of the transport body 70 in situ around a vertical axis. In addition, the levitating height of the transport body 70 from the floor surface 3A can be changed. Therefore, the transport body 70 is also movable in the vertical direction. As described above, the transport body 70 is capable of changing its position in each of the X, Y and Z directions. However, the transport body 70 is capable of translation movement in a plurality of directions in addition to one of the XYZ directions.

As illustrated in FIG. 1, for example, the tip of the substrate holder 72 is configured as a fork 73 capable of sandwiching the area where the three lifting pins 68 or 69 are provided, on the opposite sides of the area. The substrate holder 72 is configured to have, for example, a length capable of delivering a wafer W to the stage 17 by opening the gate valve G3 and inserting the wafer W into the processing container 11 through the opening 16 while the main body 71 is being positioned inside the housing 12.

In addition, the length in the short side direction of the housing 12, which is rectangular in plan view, is such that two transport bodies 70, each of which holds a wafer W, can pass by each other while being aligned side by side. In this example, wafers W are transferred by using a plurality of transport bodies 70 provided in housing 12.

### <Controller>

The substrate processing apparatus 2 further includes a controller 5. The controller 5 is configured with a computer including a CPU and a storage, and controls each part of the substrate processing apparatus 2. A storage stores a program in which a group of steps (instructions) for controlling the operation of the processing container 11 or the like in various processing steps are assembled. This program is stored, for example, in a storage medium, such as a hard disk, a compact disk, a magneto optical disk, a memory card, or a nonvolatile memory, and is installed from the storage medium to the computer. The storage also stores a program for controlling the wafer transfer operation of the transport body 70, and also stores a program relating to a depressurization process for previously evacuating the transfer space S1 before the wafer transfer operation.

### <Transfer Operation>

Next, an example of a wafer W transfer operation in the substrate processing apparatus 2 having the above-described configuration will be described. First, a carrier C containing wafers W to be processed is placed on a load port 63. Then, the transfer mechanism 66 in the atmospheric transfer chamber 61 takes out a wafer W from the carrier C, carries the wafer W into a load-lock chamber 62, and delivers the wafer W to the stage 67 by cooperative action with the lifting pins 68. Thereafter, when the transfer mechanism 66 is withdrawn from the load-lock chamber 62, the gate valve G1 is closed to switch the interior of the load-lock chamber 62 from the air atmosphere to the vacuum atmosphere.

When the load-lock chamber 62 becomes a vacuum atmosphere, the gate valve G2 is opened. At this time, within housing 12, a transport body 70 stands by in the vicinity of the connection position of the load-lock chamber 62 in a posture facing the load-lock chamber 62. Then, as will be described later, the transport body 70 is raised by magnetic levitation.

Next, the substrate holder 72 of the transport body 70 is moved into the load-lock chamber 62, and the wafer W is received by the fork 73 of the substrate holder 72 from the stage 67 via the lifting pins 68. Subsequently, the substrate holder 72, which is holding the wafer W, is withdrawn from the load-lock chamber 62. The transport body 70 is retracted to a side position of the processing container 11 in which the wafer W is to be processed, and the tip side of the substrate holder 72 holding the wafer W is disposed on the side of the gate valve G3.

In this way, when the tip side of the substrate holder 72 reaches the side of the gate valve G3, the gate valve G3 is opened, the main body 71 rotates, retracts, and advances as appropriate, and the wafer W is transferred into the processing container 11 and reaches above the stage 17. Next, the wafer W is delivered to the stage 17 via the lifting pins 69, and the transport body 70 is withdrawn from the processing container 11. In addition, after closing the gate valve G3, the processing of the wafer W is started.

That is, while the wafer W placed on the stage 17 is heated as necessary to raise the temperature to a preset temperature, if a processing gas supplier is provided, a processing gas is supplied into the processing container 11. As a result, desired processing is performed on the wafer W. After the processing of the wafer W is executed for a preset period of time, the heating of the wafer W is stopped, and the supply of the processing gas is stopped.

Thereafter, the wafer W is transferred in the reverse order of the carry-in, and the wafer W is returned from the wafer processing container 11 to the load-lock chamber 62. In addition, after switching the atmosphere of the load-lock chamber 62 to the atmospheric pressure atmosphere, the wafer W in the load-lock chamber 62 is taken out by the wafer transfer mechanism 66 on the atmospheric transfer chamber 61 side and is returned to a predetermined carrier C.

The substrate transfer module 1 will be described in detail below. As described above, the substrate transfer module 1 includes a housing 12 forming a transfer space S1 in which a wafer W is transferred, an evacuation mechanism 14 configured to evacuate the transfer space S1 to a vacuum atmosphere, and a transport body 70. The bottom of the housing 12 is configured as a floor 3 in which a number of electromagnets are installed. Since the substrate processing apparatus 2 is installed in a clean room as described above, the exterior of the housing 12 is in the air atmosphere. The space having the air atmosphere outside the housing 12 will be referred to as an external space 100. As will be described later, the atmosphere of the transfer space S1 is separated from the atmosphere of the external space 100, the transfer space S1 is configured to have a high airtightness, and the transfer of the wafer W is performed in the transfer space S1 which is in a state of a vacuum atmosphere of, for example, 300 Pa or less.

### <Transport Body>

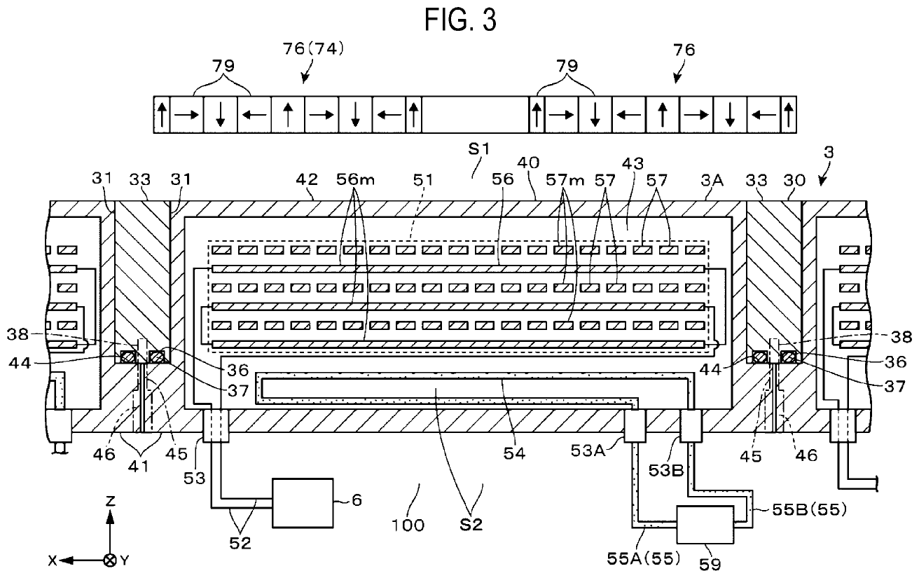

FIG. 3 is a vertical cross-sectional side view taken along line A-A′ illustrated in FIG. 2 and illustrates magnet units 74, and electromagnets (first coils 56 and second coils 57) included in the floor 3. As illustrated in FIGS. 2 and 3, the main body 71 is configured, for example, in a square shape in plan view. The bottom surface of the main body 71 faces the floor 3 and is parallel to the floor 3. FIGS. 2 and 3 illustrate a state in which the main body 71 is placed above the floor 3 such that the four sides forming the periphery of the main body 71 are parallel to the X direction and the Y direction, respectively, and the substrate holder 72 extends in the Y direction. Although the arrangement of the transport body 70 is arbitrarily changeable, for convenience of description of the configuration, the magnet units 74 of the transport body 70 will be described assuming that the transport body 70 is arranged as illustrated in FIG. 2.

### <Magnet Unit>

As illustrated in FIGS. 2 and 3, each magnet unit 74 is a plate-like body configured in a rectangular shape in plan view, in which the magnet units have the same shape as each other and are similarly configured with a plurality of magnets as will be described in detail later. Each of these magnet units 74 extends in the horizontal direction, and the long sides thereof are arranged along the four sides of the outer edge of the main body 71. In adjacent magnet units 74, on a longitudinal extension line of one magnet unit 74, a longitudinal end of the other magnet unit 74 is located. With such an arrangement, the four magnet units 74 are configured to form an annular body and are arranged to be rotationally symmetrical about the Z axis.

In FIG. 3, the two magnet units 74 with the long sides arranged in the X direction, will be called first magnet units 75, and the two magnet units 74 with the long sides arranged in the Y direction will be called second magnet units 76. As two second magnet units 76 are representatively illustrated in FIG. 3, each magnet unit 74 includes nine permanent magnets 79. The nine permanent magnets 79 have an elongated prismatic shape extending in the Y direction and arranged in the X direction.

In FIG. 3, the direction of the north pole of each permanent magnet 79 is schematically indicated by an arrow. As illustrated in the figure, each permanent magnet 79 is arranged such that the N pole is oriented in the Z direction or the X direction, and the N pole directions of adjacent permanent magnets 79 differ from each other by 90°. Specifically, when viewed in order from one end side (+X side) in the X direction toward the other end side (−X side), the N poles of respective permanent magnets 79 are arranged to face +Z, −X, −Z, +X, +Z, −X, −Z, +X, and +Z sides, and the directions of the magnetic poles changes periodically. That is, the nine permanent magnets 79 form a Halbach array, and a stronger magnetic field is formed on the lower side than on the upper side, thereby obtaining a high levitation force. The first magnet units 75 have the same configuration as the second magnet units 76, except that the length direction thereof is along the X direction. Therefore, a description of the first magnet units 75 corresponds to that obtained by rereading the description of the above-described second magnet units 76 assuming that the second magnet units 76 are rotated by 90° around the Z-axis.

### <Floor>

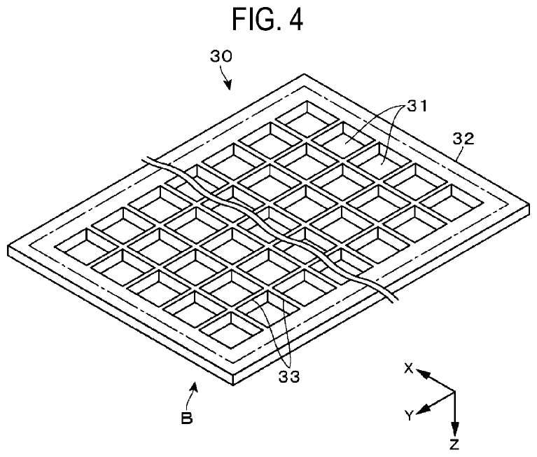

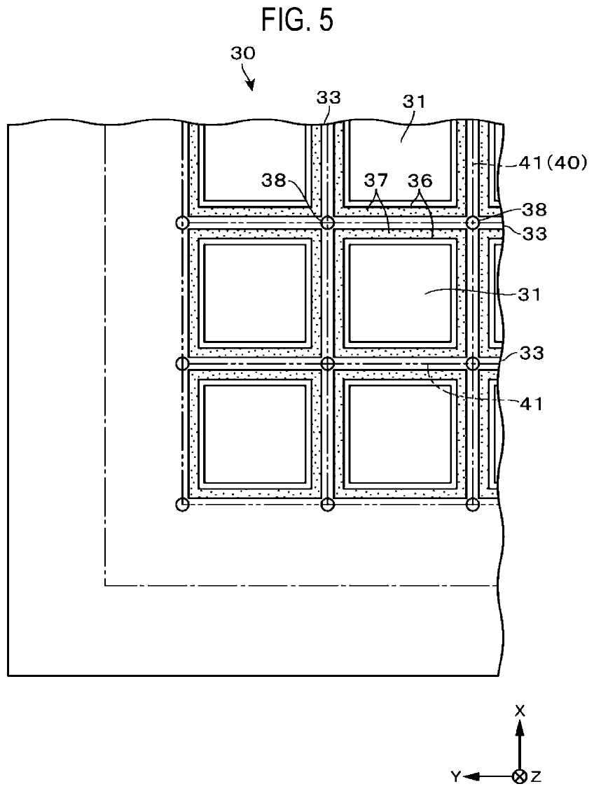

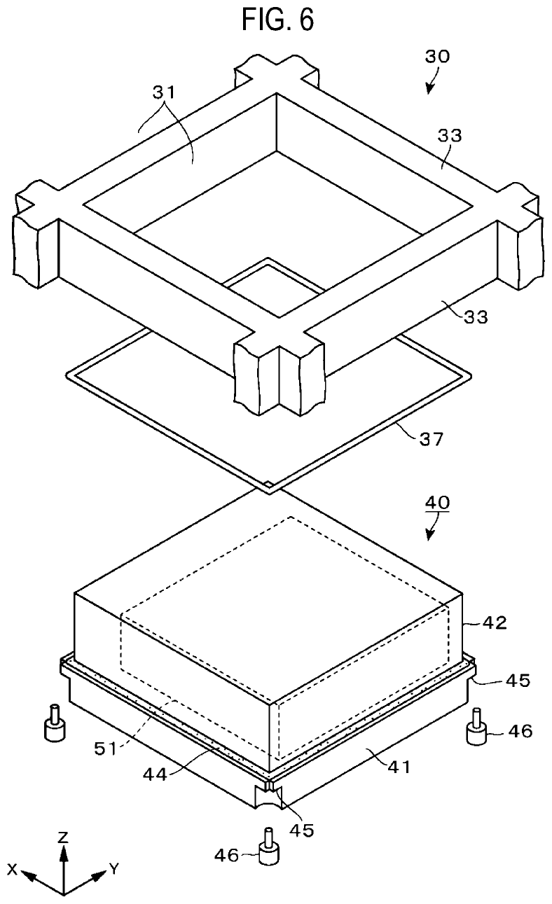

The floor 3, which is the bottom of the housing 12, includes a grid-shaped frame body 30 having a plurality of through-holes 31 defined therein, and a plurality of case bodies 40 provided, one for each of the through-holes 31. FIG. 4 is a bottom perspective view illustrating the frame body 30, and FIG. 5 is an enlarged bottom view of the portion B illustrated in FIG. 4, in which the outer edge of each of the case bodies 40 provided in the frame body 30 is indicated by a chain double-dashed line. FIG. 6 is a partially exploded view of the floor 3 in the present embodiment. Although almost the entire floor 3 is configured with the frame body 30 and the case bodies 40, these members are not provided in the rear end portion of the floor 3, for example, outside a transport body 70 moving region. Instead, the rear end portion is used as a region where an exhaust port 14A opens (see FIG. 1). The transfer space S1 is evacuated by the evacuation mechanism 14 such as a vacuum pump via the exhaust port 14A.

As illustrated in FIG. 4, the frame body 30 includes a rectangular outer frame 32 and a plurality of crosspieces 33 extending in the X direction and the Y direction within the outer frame 32. These crosspieces 33 arranged in a grid shape partition the space inside the outer frame 32 and define a plurality of through-holes 31 together with the inner edge of the outer frame 32. Therefore, the frame body 30 is a hole forming member. The chain-dashed lines in FIGS. 4 and 5 indicate the peripheral edge of the inner wall of the housing 12 overlapping the frame body 30. Through-holes 31 are each square-shaped in plan view and are arranged at equal intervals in both the X direction and the Y direction. In addition, the interval between the through-holes 31 adjacent to each other in the X direction is equal to the interval between the through-holes 31 adjacent to each other in the Y direction. The shape of the through-holes 31 and the case bodies 40 is not limited to a square shape, and may be, for example, a circular shape in plan view.

On the bottom surface of the frame body 30, an annular arrangement groove 36 is formed in the hole edge portion, which is the outer peripheral edge of each through-hole 31, and is indicated by dots in FIG. 5. The arrangement groove 36 is provided concentrically with respect to the lower opening of the through-hole 31 and is separated from the through-hole 31. An annular member 37 is arranged in each arrangement groove 36, and each annular member 37 is formed along the periphery of the through-hole 31. The annular member 37 is, for example, an O-ring that is an elastic body, and is a sealing member for sealing the through-hole 31. In addition, screw holes 38 are provided in the bottom surface of the frame body 30 at a slight distance from the four corners of each through-hole 31. The detailed arrangement of the screw holes 38 will be described later together with the configuration of the flanges 41 of the case bodies 40.

### <Case Body Forming Floor>

The case bodies 40 block the through-holes 31 in the frame body 30 to separate the transfer space S1, which has a vacuum atmosphere, from the external space 100, which has an air atmosphere. As illustrated in FIGS. 3 and 6, a case body 40 includes a case main body 42, a flange 41 protruding from the lower side periphery of the case main body 42, and a rectangular parallelepiped internal space 43 provided inside the case main body 42. The internal space 43 is a closed space having an atmospheric pressure atmosphere, which is separated from the transfer space S1, and the internal space 43 and the external space 100 form a non-transfer space S2 in which the atmosphere is separated from the transfer space S1 and transfer by a transport body 70 is not performed.

An electromagnet or the like is accommodated in the internal space 43, which has a closed space having atmospheric pressure. In order to prevent the case body 40 from being strongly magnetized by the electromagnet and hindering the operation control of the transport body 70, the case body 40 is made of a paramagnetic material or a diamagnetic material. Specifically, the case body is made of, for example, aluminum (Al). For the same reason, the frame body 30 is also made of a paramagnetic material or a diamagnetic material, such as aluminum, like the case body.

The case main body 42 has a rectangular parallelepiped shape that is square in plan view, and the size of the case main body 42 in plan view is approximately the same as the size of the through-hole 31 in plan view. By being provided on the lower side of the case main body 42, the flange 41 is located lower than the top surface of the case main body 42. The flange 41 has a square shape in plan view and is slightly larger than the through-hole 31 in the frame body 30 in plan view.

In the state in which the upper portion of the case main body 42 is inserted into the through-hole 31 from below, the flange 41 is screw-fixed to the frame body 30 to overlap the lower side of the hole edge portion of the through-hole 31. The top surface of the case main body 42 is disposed at approximately the same height as the top surface of the frame body 30, and forms the floor surface 3A together with the top surface of the frame body 30 and faces the transfer space S1. In addition, as illustrated in FIGS. 3 and 5, the side surface of each flange 41 installed in the frame body 30 as described above is close to and faces the side surface of another adjacent flange 41 in the X and Y directions.

Incidentally, supplementally describing the configuration of the flange 41, the top surface of the flange 41 is configured as a contact surface 44 that comes into contact with the annular member 37, but the contact surface 44 is, for example, polished to form an annular smooth surface. Therefore, the annular member 37 has high adhesion over the entire periphery of the contact surface 44, and the sealing performance of the through-hole 31 is enhanced. In order to reduce the manufacturing cost of the apparatus, this polishing process is locally applied to the contact surface 44 on the outer surface of the case body 40, which is involved in this sealing performance. Therefore, the surface roughness of the contact surface 44 is smaller than that of other regions of the outer surface, such as the top surface of the case body 40. The surface roughness Ra of the contact surface 44 polished for sealing as described above is, for example, 1.6 μm or less, and more preferably, for example, 0.8 μm or less.

Furthermore, as described above, the flange 41 is square-shaped in plan view, and a notch is formed at each of four corners of the square. The lower side of the notch is hollowed out more toward the center side of the flange 41 than the upper side of the notch, so that thin regions 45 having a small thickness in the Z direction are respectively formed at the four corners of the flange 41. Since screws 46 are inserted from below into the screw holes 38 in the frame body 30, the screws 46 and the screws in the screw holes 38 are screw-engaged with each other, and the thin regions 45 of the flange 41 are sandwiched between the heads of the screws 46 and the bottom surface of the frame body 30, the case body 40 is fixed to the frame body 30 as described above. By being screw-fixed in this way, the annular member 37, which is an elastic body, is crushed and brought into close contact with each of the arrangement groove 36 of the frame body 30 and the contact surface 44 of the flange 41 by its restoring force, and the through-hole 31 is sealed as described above. Thus, the atmosphere is separated between the transfer space S1 and the external space 100.

In addition, the screws 46 and the screw holes 38 are arranged in a matrix form in plan view. In addition, the corners of the flanges 41 of adjacent case bodies are close together, and a set of screws 46 and screw holes 38 are provided for fixing respective corners, which are so close together. Therefore, a set of screw holes 38 and screws 46 are used to fix up to four case bodies 40.

The internal space 43 of the case body 40 will be described with reference to FIG. 3. An electromagnet unit 51 is accommodated in the internal space 43. By being provided in the internal space 43 of the case body 40 in this way, the electromagnet unit 51 is provided to overlap the through-hole 31 in the opening direction (vertical direction) of the through-hole 31. The electromagnet unit 51 includes a first coil 56 having a winding axis extending in the Y direction and a second coil 57 having a winding axis extending in the X direction. A large number of first coils 56 are provided to be spaced apart from each other in the Y direction, and a plurality of second coils 57 are provided to be spaced apart from each other in the Y direction. Each of the first coil 56 and the second coil 57 is an electromagnet.

The first coil 56 and the second coil 57 are provided with conductive paths 56m and 57m, respectively. A plurality of conductive path forming layers, in each of which a large number of conductive paths 56m extend in the X direction and are spaced apart from each other in the Y direction, and a plurality of conductive path forming layers, in each of which a large number of conductive paths 57m extend in the Y direction and are spaced apart from each other in the X direction, are alternately overlapped each other in the Z direction to form an electromagnet unit 51. The conductive paths 56m having the same position in the Y direction are connected to each other by wires provided in the Z direction at the ends of the electromagnet unit 51 in the X direction to form the above-described first coils 56. The conductive paths 57m having the same position in the X direction are connected to each other by wires provided in the Z direction at the ends of the electromagnet unit 51 in the X direction to form the above-described second coils 57. Except for the end portions of the electromagnet unit 51, the conductive paths 56m and the conductive paths 57m, which overlap vertically, are insulated from each other.

Respective wires 52 forming power feed lines connected to the first coils 56 and the second coils 57 are drawn out to a portion under the floor of the housing 12, that is, to the external space 100 through the lower portion of the case body 40. The wires 52 drawn out to the external space 100 in this manner are connected to a power feeder 6 provided in the external space 100. In FIG. 3, reference numeral 53 denotes a connector provided in the lower portion of the case body 40. The portions of the wires 52 formed inside the case body 40 and the portions provided outside the case body 40 are interconnected via the connector 53.

As for the wires 52, although the wire 52 of one first coil 56 is illustrated to be connected to the power feeder 6 in FIG. 3, each first coil 56 and each second coil 57 are connected to the power feeder 6 via the wires 52. The power feeder 6 includes a power source and an adjustment mechanism that individually adjusts the amounts of current, which are supplied from the power source to each of first coil 56 and each second coil 57, respectively. The power feeder 6 individually adjusts the current for each coil of one case body 40, and also independently adjusts the current to the first coils 56 and the current to the second coils 57 between the case bodies 40. With such a configuration, a magnetic field formed in each portion on the floor 3 can be adjusted freely, and the transport body 70 can be moved in each direction as described with reference to FIG. 1. Although it has been described that a repulsive force is used to move the transport body 70, an attractive force may be used in combination with the repulsive force to perform a control such as holding the transport body 70 at a desired location on the floor by balancing the repulsive force and the attractive force. That is, the present disclosure is not limited to the operation control using only a repulsive force.

In addition, the configuration inside the case body 40 will be described. A flow path 54 for a fluid, such as water, is formed in the case body 40. The flow path 54 forms a cooler that cools the interior of the case body 40, in which one end and the other end of the flow path 54 are connected respectively to one ends of pipes 55A and 55B, which are provided in the external space 100, via connectors 53A and 53B, which are provided in a lower portion of the case body 40. The other ends of the pipes 55A and 55B are routed through the external space 100 and are connected to a chiller 59 that is provided in the external space 100 as well, and the pipes 55A and 55B, the chiller 59, and the flow path 54 form a water circulation path. The pipe 55A is a water supply pipe to the chiller 59, and the pipe 55B is a water discharge pipe from the chiller 59. The chiller 59 includes a pump configured to circulate water, and a flow path connected to the supply pipe 55A and the discharge pipe 55B and configured to adjust the temperature of the water flowing therethrough to a predetermined temperature by heat exchange.

The water having the temperature adjusted by the chiller 59 is supplied to the flow path 54 inside the case body 40. The electromagnet unit 51, which has generated heat due to electricity, is cooled by heat exchange with the water in the flow path 54, and the temperature of the electromagnet unit 51 is adjusted to a preset temperature range. As a result, for the first coil 56 and the second coil 57, changes in electrical characteristics such as resistance values due to the temperature are suppressed. Accordingly, since magnetic fields formed on the floor 3 are suppressed from being displaced due to the heat generation of the electromagnet units 51, the position of the transport body 70 can be controlled with high accuracy. For convenience of illustration, the power feeder 6 and the chiller 59 are illustrated in a portion under the floor of the housing 12, but are arranged, for example, at a location distant from the portion under the floor.

The wires 52 connected to the above-described electromagnet unit 51 is coated with a resin sheath for the purpose of, for example, protection and insulation. Further, the pipes 55 (55A, 55B) through which the cooling water flows are made of, for example, resin, so that the pipes can be easily installed. It is assumed that the wires 52 coated with a resin sheath and the resin pipes 55 are arranged in the transfer space S1 which has a vacuum atmosphere. In that case, gas is emitted from each of these resin-made members. In that case, there is a concern that the components of the gas (outgas) may adhere to a wafer W and the wafer W may be contaminated.

There is also a concern that the pressure in the transfer space S1 may become higher than a set value due to outgas. In that case, various foreign substances remain in the transfer space S1, so there is a concern that the foreign substances may adhere to a wafer W or an unintended reaction between the foreign substances and the wafer W may occur. Although it has been described that outgas is emitted from the resin members, the present disclosure is not limited thereto. For example, with regard to the wires 52, it is also conceivable that a slight amount of outgas may be emitted from the wires 52 themselves.

However, in the above-described substrate transfer module 1, since the through-holes 31 formed in the floor 3 of the housing 12 are blocked by the case bodies 40 having the flanges 41, the atmosphere of the transfer space S1, which has a vacuum atmosphere S1, is separated from the non-transfer space S2 including the external space 100 and the internal spaces 43 inside the case bodies 40. One ends of the wires 52 and the pipes 55 are connected respectively to the electromagnet units 51 and the flow path 54 in the case body 40, while the other ends are drawn downward from the case body 40 and are connected respectively to the power feeder 6 and the chiller 59 provided in the external space 100. As described above, since the wires 52 and the pipes 55 are provided in the non-transfer space S2 from one ends to the other ends, it is possible to prevent outgas from being emitted from the wires 52 and the pipes 55 to the transfer space S1. Therefore, the pressure in the transfer space S1 is prevented from becoming higher than a set value, and the cleanliness of the transfer space S1 is prevented from being deteriorated due to outgas. As a result, it is possible to prevent a decrease in the yield of semiconductor products manufactured from a wafer W.

### Second Embodiment

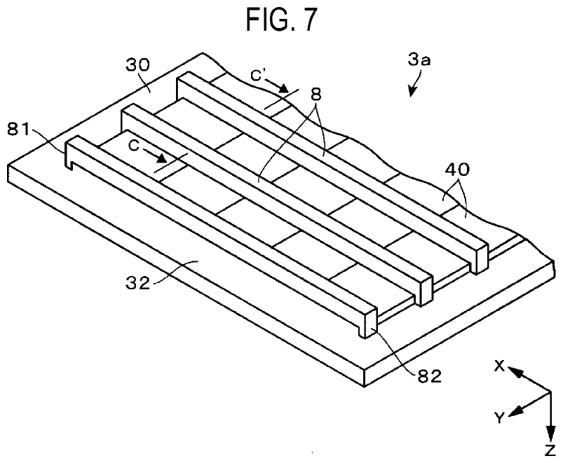

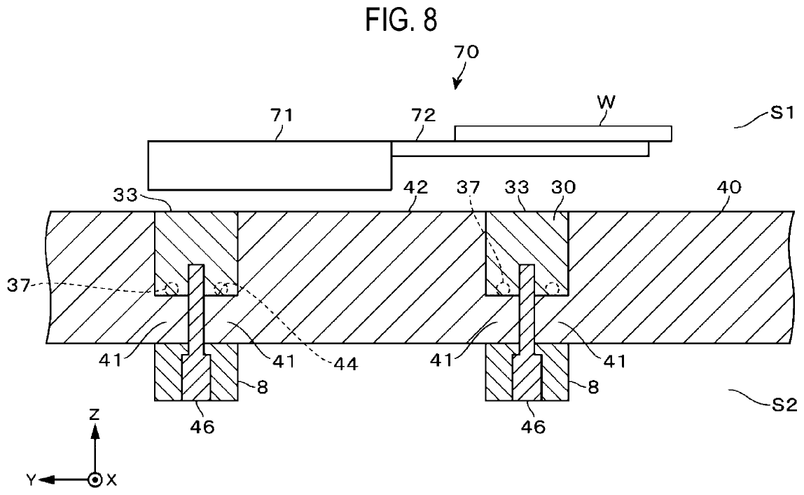

The floor 3a of the substrate transfer module according to a second embodiment of the present disclosure will be described with reference to FIGS. 7 and 8. In addition, in the following description of each embodiment, the differences from the first embodiment will be mainly described, and a description of the same configuration as that in the first embodiment will be omitted. FIG. 8 illustrates a cross-sectional view taken along line C-C′ illustrated in FIG. 7. FIG. 8 omits the internal space 43 of the case body 40 and various mechanisms arranged in the internal space 43.

The floor 3a in the present embodiment includes a plurality of reinforcing members 8 that are connected to the outer frame 32 and a plurality of case bodies 40 from below to connect the outer frame 32 and the plurality of case bodies 40 to each other. Regarding the frame body 30, the outer frame 32 is wider and stronger than the crosspieces 33. By connecting the case bodies 40 to the outer frame 32 via the reinforcing members 8, the stress received by the case bodies 40 and the crosspieces 33 connected to the case bodies 40 due to the atmospheric pressure is distributed to the reinforcing members 8 and the outer frame 32. Therefore, in the present embodiment, the distortion of the case bodies 40 and the crosspieces 33 due to the atmospheric pressure is prevented more reliably.

The plurality of reinforcing members 8 are so-called beams extending in the X direction and arranged at intervals in the Y direction. Each reinforcing member 8 is installed below a crosspiece 33 extending in the X direction, and end portions 81 and 82 in the extending direction are attached to the bottom surface of the outer frame 32 by, for example, screws (not illustrated). FIG. 8 illustrates an example in which the flange 41 of the case body 40 and the reinforcing members 8 are sandwiched between the heads of the screws 46 and the frame bodies 30 to be fixed to each other, but the installation of the reinforcing members 8 to the frame bodies 30 is optional rather than being limited to such an example.

The shape of the reinforcing member is not limited to the beam-like shape of the reinforcing members 8. For example, the reinforcing member may have the shape of a cup having an open top, in which the opening edge of the cup is connected to the outer frame, and the bottom surface inside the cup is connected to the bottom surface of the case body 40. When the reinforcing member is configured as a cup in this way, a plurality of through-holes may be formed in the bottom of the cup, and the pipes 55 and the wires 52 may be drawn out downward through the through-holes.

### Third Embodiment

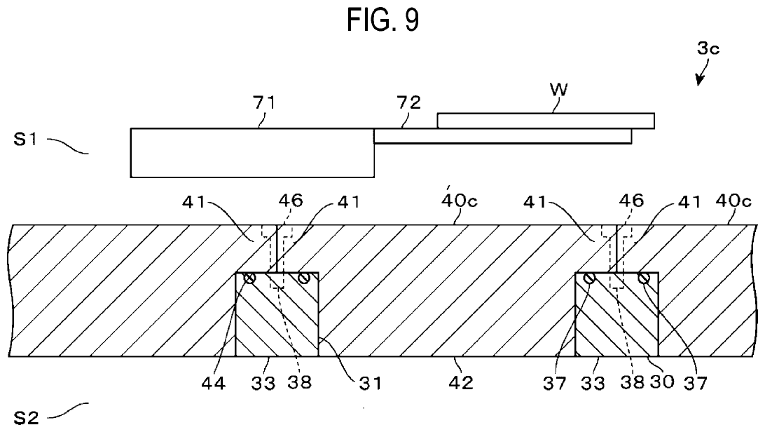

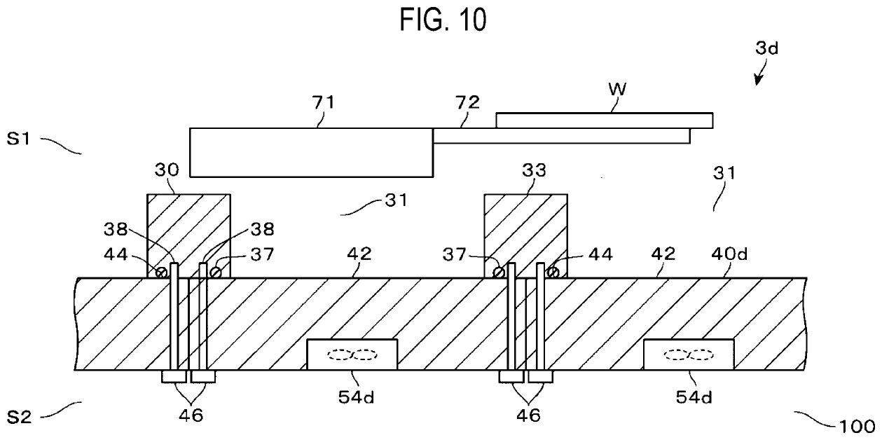

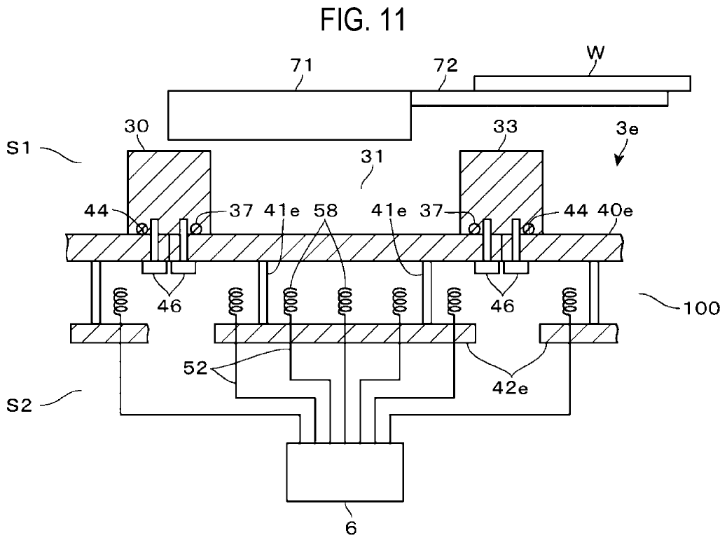

A third embodiment of the present disclosure will be described with reference to FIG. 9. FIG. 9 and subsequent FIGS. 10 and 11 are vertical cross-sectional side views illustrating the same locations as FIG. 3 relating to the first embodiment. A case body 40c forming a floor 3c illustrated in FIG. 9 may have a configuration in which the flange 41 is provided on the upper side instead of being provided on the lower side, and the case main body 42 is inserted into a through-hole 31 in the frame body 30 from the upper side (that is, the transfer space S1 side). That is, in the third embodiment, the flange 41 is placed in the transfer space S1 which has a vacuum atmosphere. Since the atmospheric pressure acts on the case body 40c from below, screws 46 are provided such that the heads of the screws 46 presses the flange 41 downward. That is, screw holes 38 is formed in the top surface of the frame body 30, the screws 46 are inserted into the screw holes 38 from above, and the flange 41 is screw-fixed to be sandwiched between the heads of the screws 46 and the frame body 30. However, the screws 46 receive relatively strong upward stress from the flange 41 due to the atmospheric pressure. Accordingly, the first embodiment is preferable since the load on the screws 46 is suppressed unlike this and the deterioration of the screw 46 is suppressed.

### Fourth Embodiment

Next, a floor 3d in a fourth embodiment of the present disclosure will be described with reference to FIG. 10. A case body 40d forming the floor 3d of the present embodiment is not provided with a flange and has a square shape larger than a through-hole 31 in plan view. In addition, the outer edge portion of the top surface of the case body 40d overlaps the hole edge portion of the through-hole 31 from below. The screws 46 are long screws and penetrate the peripheral edge portion of the case main body 42 in the Z direction and are inserted into screw holes 38 to fix the case body 40d to the frame body 30.

In this way, the case body surrounding electromagnets is not limited to being provided in the through-hole 31, nor is it limited to being provided with the flange 41. However, in the fourth embodiment, since the top surface of the case body 40d is lower than the top surface of the frame body 30, the amount of current supplied to the electromagnet unit 51 becomes relatively large when levitating the transport body 70 from the top surface of the frame body 30. In other words, the configuration of the above-described first embodiment is preferable because there is an advantage in that the current required to levitate the transport body 70 can be reduced and the cost required for the operation of the apparatus can be reduced.

In place of the flow path 54 connected to the chiller 59 illustrated in FIG. 3, fans 54d are provided in the case body 40d as a cooler to be capable of discharging gas downward from the case body 40d. For example, a through-hole connecting the external space 100 to the interior of the case body 40d is formed in the bottom of the case body 40d. By the fans 54d, the air introduced into the case body 40d from the external space 100 through the through-hole is discharged to the case body 40d, and the interior of the case body 40d is cooled by the flow of the air. Thus, the cooler that cools the interior of the case body is not limited to the cooling water flow path 54.

### Fifth Embodiment

A floor 3e of a substrate transfer module in a fifth embodiment of the present disclosure will be described with reference to FIG. 11. Since the floor 3e is configured with a square plate member 40e having a side slightly larger than the through-hole 31 in plan view and the peripheral edge portion of the plate member 40e overlaps the hole edge portion of the through-hole 31 from below, the through-hole 31 is blocked. Connection posts 41e extend downward from the bottom surface of the plate member 40e, and a pedestal 42e is provided to be suspended from the connection posts 41e. Coils 58 forming an electromagnet is provided on the pedestal 42e at a position below the through-hole 31.

Thus, the present disclosure is not limited to a configuration in which coils are surrounded by a case body as described in the first to fourth embodiments. However, from the viewpoints of protecting the coils and facilitating handling, it is advantageous to have a configuration including a case body. Unlike the first coil 56 and the second coil 57 described with reference to FIG. 3, the coil 58 of the fifth embodiment is disposed such that the winding axis thereof extends in the Z direction, and below the through-hole 31, a plurality of coils are provided to be distributed on the XY plane. Thus, the configuration of the coil is not limited to the configuration described with reference to FIG. 3. In order to prevent complication of the drawing, only the wires 52 connected to one end side of the coil 58 are illustrated, and the wires 52 on the other end side are omitted, but the other end side is also provided in the external space 100 in the same manner as the one end side.

### (Modification)

Although the arrangement groove 36 in the outer frame 32 and the opening of the through-hole 31 are spaced apart from each other in each embodiment, the arrangement groove 36 may be connected to the lower opening. Specifically, the lower end portion of the through-hole 31 is configured to widen slightly to form a step. An O-ring is disposed below this step, and the O-ring is pressed against by a flange 41 disposed below the O-ring, providing a seal. That is, the O-ring is not limited to being disposed in the groove. The annular member 37, which is a sealing member, has been described as an O-ring, which is an elastic body. However, the sealing member is not limited to being an elastic body as long as it can be tightly sealed between the arrangement groove 36 and the flange 41, and may be, for example, a metal gasket.

In each embodiment, the arrangement groove 36 and the annular member 37 are arranged in the hole edge portion of the through-hole 31, and the contact surface 44 is arranged on the top surface of the flange 41, but may be arranged vice versa. Moreover, the present disclosure is not limited to providing a plurality of sets of through-holes 31 and case bodies 40 and may have a configuration that is provided with only one set of relatively large ones.

The transfer space S1 in the present embodiment is brought into a vacuum atmosphere by the evacuation mechanism 14, but may have, for example, a normal pressure air atmosphere, rather than being limited thereto. Even when the transfer space S1 having an air atmosphere, foreign substances coming out of the sheath coated on the wires 52 provided in the non-transfer space S2 from being supplied to the transfer space S1, so that the transfer space S1 can be made to have a clean atmosphere. The substrate to be transferred is not limited to a wafer W, and may be, for example, a rectangular substrate such as a substrate for manufacturing a flat panel display (FPD).

It should be noted that the embodiments disclosed herein are exemplary in all respects and are not restrictive. The above-described embodiments may be omitted, replaced, modified, and combined in various forms without departing from the scope and spirit of the appended claims.

According to the present disclosure, it is possible to suppress the influence of an external non-transfer space on a transfer space in which a substrate transport body moves by magnetic levitation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate transfer module comprising:
a transfer space in which a transport body including a magnet moves in a lateral direction while being levitated from a floor by magnetic force to transfer a substrate;
a hole forming member having a through-hole formed in a vertical direction;
a partition member that forms the floor by overlapping a hole edge portion of the through-hole in the vertical direction to block the through-hole, and defines the transfer space having an atmosphere that is separated from a non-transfer space including a portion under the floor outside the transfer space; and
a plurality of electromagnets provided in the non-transfer space at positions overlapping the through-hole to move the transport body in the lateral direction, wherein each of the electromagnets is individually fed with power from a power feeder provided in the non-transfer space via a power feed line.

2. The substrate transfer module of claim 1, wherein the partition member is a portion of a case body,
wherein the plurality of electromagnets is installed in an interior of the case body,
wherein the non-transfer space includes the interior of the case body and the portion under the floor that is a region under the case body, and
wherein the power feed line is installed from the interior of the case body to the portion under the floor.

3. The substrate transfer module of claim 2, wherein the floor forms a bottom portion of a housing,
wherein an exhaust mechanism is provided to exhaust the transfer space inside the housing to create a vacuum atmosphere, and
wherein the non-transfer space is a space having an air atmosphere outside the housing.

4. The substrate transfer module of claim 3, wherein the case body includes a case main body surrounding the electromagnets and a flange formed on a side periphery of the case body, and
wherein the flange overlaps the hole edge portion in the vertical direction, and the case body is installed within the through-hole.

5. The substrate transfer module of claim 4, wherein the flange overlaps the hole edge portion from below,
wherein the case main body includes a top surface provided at a position higher than the flange, and
wherein the top surface forms a floor surface facing the transfer space.

6. The substrate transfer module of claim 5, wherein an annular member, which is an elastic body and is formed along a periphery of the through-hole, is interposed between the flange and the hole edge portion, and
wherein a contact surface of the flange with respect to the annular member has a surface roughness smaller than a surface roughness of the top surface of the case main body.

7. The substrate transfer module of claim 2, further comprising:
a cooler configured to cool the interior of the case body.

8. The substrate transfer module of claim 3, wherein the hole forming member is a grid-shaped frame body, which includes an outer frame and a plurality of crosspieces extending in a front-rear direction and a left-right direction within the outer frame to define a plurality of through-holes, and
wherein the case body is provided in each of the through-holes such that there is a plurality of case bodies.

9. The substrate transfer module of claim 8, further comprising:
a reinforcing member connected to the outer frame and each of the case bodies from below and configured to connect each of the case bodies to the outer frame to prevent distortion of the each of the case bodies.

10. The substrate transfer module of claim 9, wherein the reinforcing member extends along the crosspieces extending in one of the front-rear direction and the left-right direction, and
wherein the reinforcing member includes a plurality of beams, which is connected to the outer frame at each of one end side and the other end side of the beam in an extending direction of the beam, connected to bottom surfaces of the plurality of case bodies, and installed at intervals in the other of the front-rear direction and the left-right direction.

11. A substrate transfer method for transferring, by a transport body including a magnet, a substrate in a transfer space in which an atmosphere is separated from a non-transfer space, the substrate transfer method comprising:
feeding power from a power feeder provided in the non-transfer space individually to each of a plurality of electromagnets via a power feed line, wherein the transfer space is defined by a partition member, which forms a floor by blocking a through-hole formed in a hole forming member in a vertical direction to overlap an hole edge portion of the through-hole in the vertical direction, the non-transfer space is located outside the transfer space and includes a portion under the floor, and the plurality of electromagnets is installed in the non-transfer space at positions overlapping the through-hole; and
transferring the substrate by moving the transport body in a lateral direction in a state of being levitated from the floor by a magnetic force.
